(19) United States
(12) Patent Application Publication
(10) Pub. No.: US 2015/0097286 A1
(43) Pub. Date: Apr. 9, 2015

(54) CHIP PACKAGE AND METHOD FOR FABRICATING THE SAME

(71) Applicant: XINTEC INC., Zhongli City (TW)

(72) Inventors: Wei-Luen SUEN, New Taipei City (TW); Chia-Sheng LIN, Zhongli City (TW); Yen-Shih HO, Kaohsiung City (TW); Tsang-Yu LIU, Zhubei City (TW)

(21) Appl. No.: 14/568,056

(22) Filed: Dec. 11, 2014

Related U.S. Application Data
(63) Continuation-in-part of application No. 14/251,470, filed on Apr. 11, 2014.
(60) Provisional application No. 61/811,487, filed on Apr. 12, 2013.

(51) Int. Cl. H01L 23/00

(52) U.S. Cl. CPC H01L 24/17; H01L 24/81; H01L 24/11; H01L 2224/1703; H01L 2224/16227; H01L 2224/16055; H01L 2224/16052; H01L 2224/13024; H01L 2224/11312
USPC 257/737; 438/125

(57) ABSTRACT

A chip package includes a packaging substrate, a semiconductor chip, and a plurality of conductive structures. The semiconductor chip has a central region and an edge region that surrounds the central region. The conductive structures are between the packaging substrate and the semiconductor chip. The conductive structures have different heights, and the heights of the conductive structures are gradually increased from the central region of the semiconductor chip to the edge region of the semiconductor chip, such that a distance between the edge region of the semiconductor chip and the packaging substrate is greater than a distance between the central region of the semiconductor chip and the packaging substrate.

### RELATED APPLICATIONS

This application is a Continuation-in-part of U.S. application Ser. No. 14/251,470, filed on Apr. 11, 2014, which claims priority of U.S. provisional Application Ser. No. 61/811,487, filed on Apr. 12, 2013, the entirety of which is incorporated by reference herein.

### BACKGROUND

1. Field of Invention

The invention relates to a semiconductor device, and in particular relates to a chip package and fabrication method thereof.

2. Description of Related Art

The chip packaging process is an important process when fabricating an electronic product. Chip packages not only provide chips with protection from environmental contaminants, but also provide an interface for connection between electronic elements in the chips and electronic elements outside of the chip package.

Due to reductions in the size of electronic products, forming chip packages with more functions and smaller sizes has become an important issue. However, chip packages with more functions and smaller sizes have high-density circuits, which results in a large chip warpage and can lead to some of the solder balls on the chip not being able to bond to a packaging substrate. Therefore, the durability of such chip packages is low, and the performance of the chips is impacted.

When fabricating a chip package, a semiconductor chip may be disposed on a printed circuit board by utilizing soldering or surface-mount technology (SMT). As a result, solder balls on the back surface of the semiconductor chip can be electrically connected to the printed circuit board.

The sizes of the solder balls are substantially the same and the configuration of the semiconductor chip is not designed specifically. Therefore, the conventional semiconductor chip is parallel to the printed circuit board, such that the front surface of the semiconductor chip (i.e., an image-sensing surface) is a horizontal surface. As a result, when the image-sensing surface of the semiconductor chip detects an image, light is apt to be scattered, thereby causing image distortion.

### SUMMARY

Embodiments of the invention provide a chip package, including: a packaging substrate; a chip; and solder balls disposed between the packaging substrate and the chip so as to bond the chip onto the packaging substrate, wherein the solder balls have a first size and a second size that is different from the first size.

Embodiments of the invention provide a manufacturing method of a chip package, including: forming a plurality of chips on a wafer; measuring distribution of a circuit of the chips on the wafer; disposing a plurality of solder balls on the chips on the wafer, wherein the solder balls have a first size and a second size, and the solder balls of the first size and the solder balls of the second size are arranged according to the measurement result; bonding the wafer onto a packaging substrate; and dicing the wafer to form a plurality of chip packages.

Embodiments of the invention provide a manufacturing method of a chip package, including: forming a plurality of chips on a wafer; measuring warpage of the chips on the wafer; dicing the wafer into a plurality of separated chips; disposing a plurality of solder balls on the separated chips, wherein the solder balls have a first size and a second size, and the solder balls of the first size and the solder balls of the second size are arranged according to the measurement result of the warpage; and bonding the separated chips onto corresponding packaging substrates.

An aspect of the present invention is to provide a chip package.

According to an embodiment of the present invention, a chip package includes a packaging structure, a semiconductor chip, and a plurality of conductive structures. The semiconductor chip has a central region and an edge region that surrounds the central region. The conductive structures are between the packaging structure and the semiconductor chip. The conductive structures have different heights, and the heights of the conductive structures are gradually increased from the central region of the semiconductor chip to the edge region of the semiconductor chip, such that a distance between the edge region of the semiconductor chip and the packaging structure is greater than a distance between the central region of the semiconductor chip and the packaging structure.

In one embodiment of the present invention, the top view shapes of the conductive structures include round, elliptical, polygonal, or a combination of shapes thereof.

In one embodiment of the present invention, the semiconductor chip has a semiconductor substrate. The semiconductor substrate has a bonding pad and a hollow region. The bonding pad is exposed through the hollow region. The semiconductor chip further includes an isolation layer. The isolation layer is located on a surface of the semiconductor substrate facing the packaging substrate and a surface of the semiconductor substrate surrounding the hollow region.

In one embodiment of the present invention, the semiconductor chip further includes a redistribution layer. The redistribution layer is located on the isolation layer and the bonding pad.

In one embodiment of the present invention, the semiconductor chip further includes a protection layer. The protection layer is located on the redistribution layer and the isolation layer. The protection layer has a plurality of openings to expose the redistribution layer.

In one embodiment of the present invention, the conductive structures are located on the redistribution layer in the openings of the protection layer.

In one embodiment of the present invention, calibers of the openings of the protection layer are gradually decreased from the central region of the semiconductor chip to the edge region of the semiconductor chip.

An aspect of the present invention is to provide a method for fabricating a chip package.

According to an embodiment of the present invention, a method for fabricating a chip package includes the following steps. (a) A plurality of conductive structures with different heights are formed on a semiconductor chip, and the heights of the conductive structures are gradually increased from a central region of the semiconductor chip to an edge region of the semiconductor chip. (b) The semiconductor chip is mounted on a packaging substrate, such that the semiconductor chip is bended due to support of the conductive structures.

In one embodiment of the present invention, step (a) includes: a caliber of an opening of a printing nozzle is adjusted, such that a conductive glue is printed on the semiconductor chip from the opening of the printing nozzle with different calibers to form the conductive structures with different heights.

In one embodiment of the present invention, the method for fabricating the chip package further includes: a protection layer is formed on a redistribution layer of the semiconductor chip, and a plurality of openings with different calibers are formed in the protection layer. The calibers of the openings of the protection layer are gradually decreased from the central region of the semiconductor chip to the edge region of the semiconductor chip.

In one embodiment of the present invention, step (a) includes: the conductive structures are placed on the redistribution layer in the openings of the protection layer.

In the aforementioned embodiments of the present invention, since the conductive structures have different heights and the heights of the conductive structures are gradually increased from the central region of the semiconductor chip to the edge region of the semiconductor chip, the distance between the edge region of the semiconductor chip and the packaging structure is greater than the distance between the central region of the semiconductor chip and the packaging structure. As a result, a front surface of the semiconductor chip (i.e., an image sensing-surface) is a concave surface that can be simulated as a retinal shape. When the image-sensing surface of the semiconductor chip detects an image, light is apt to be centralized, thereby reducing the possibility of image distortion.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIGS. 1A-1E are cross-sectional views of a wafer-level packaging process of a chip package according to an embodiment of the invention;

FIG. 2 is a bottom view of chips after being disposed with the solder balls of FIG. 1C;

FIG. 3 is a cross-sectional view of a wafer-level packaging process of a chip package according to another embodiment of the invention;

FIGS. 4A-4B are cross-sectional views of a chip-level packaging process of a chip package according to one embodiment of the invention;

FIG. 5 is a side view of a chip package according to one embodiment of the present invention;

FIG. 6 is a side view of a semiconductor chip shown in FIG. 5 when being mounted to a packaging substrate;

FIG. 7 is a bottom view of the semiconductor chip shown in FIG. 6;

FIG. 8 is a cross-sectional view of the semiconductor chip taken along line 8-8 shown in FIG. 7;

FIG. 9 is a cross-sectional view of a semiconductor chip according to one embodiment of the present invention, in which the position of the cut line is the same that of FIG. 8;

FIG. 10 is a flow chart of a method for fabricating a chip package according to one embodiment of the present invention;

FIG. 11 is a cross-sectional view of a hollow region after being formed in a semiconductor substrate according to one embodiment of the present invention;

FIG. 12 is a cross-sectional view of an isolation layer and a redistribution layer after being formed on the semiconductor substrate shown in FIG. 11;

FIG. 13 is a cross-sectional view of a protection layer after being formed on the isolation layer and the redistribution layer shown in FIG. 12;

FIG. 14 is a cross-sectional view of a conductive structure after being formed on the redistribution layer shown in FIG. 13;

FIG. 15 is a cross-sectional view of a carrier shown in FIG. 14 when being removed; and

FIG. 16 is a cross-sectional view of a tape shown in FIG. 15 when being removed.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

It should be understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

A chip package according to an embodiment of the present invention may be used to package a proximity sensor, but the application is not limited thereto. The wafer scale packaging process mentioned above mainly means that after the packaging process is accomplished during the wafer stage, the wafer with chips is cut to independent packages. However, in a specific embodiment, separated chips may be redistributed overlying a supporting wafer and then be packaged, which may also be referred to as a wafer scale packaging process. In addition, the above mentioned wafer scale packaging process may also be adapted to form chip packages of multi-layer integrated circuit devices by stacking a plurality of wafers having integrated circuits. In one embodiment, the diced package is a chip scale package (CSP). The size of the chip scale package may be only slightly larger than the size of the packaged chip. For example, the size of the chip package is not larger than 120% of the size of the packaged chip.

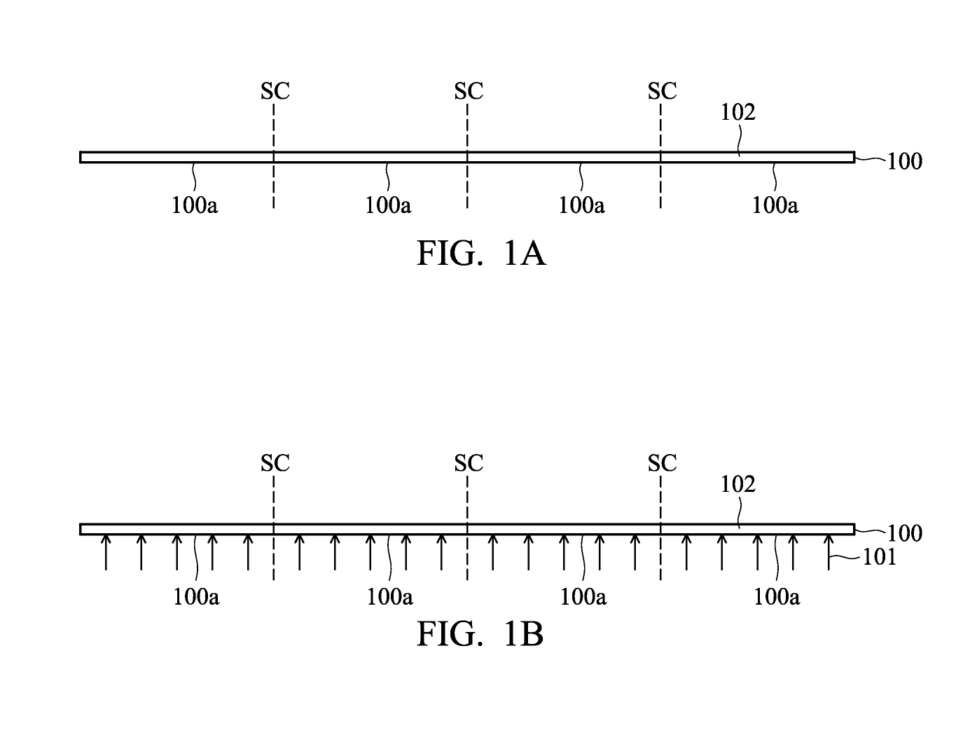

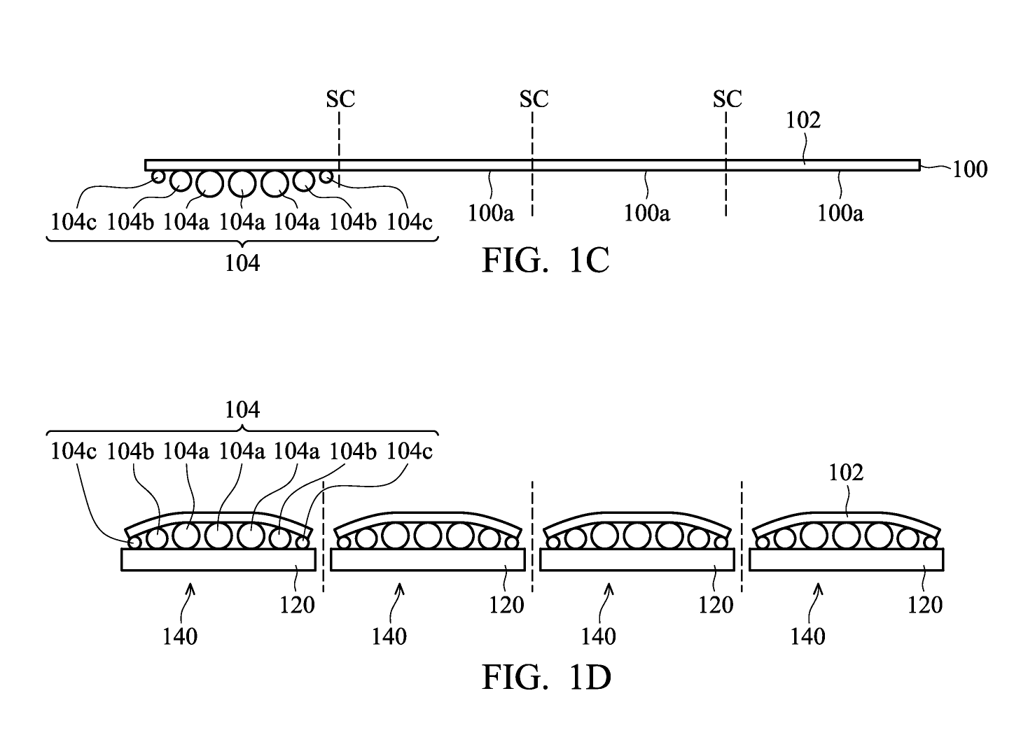

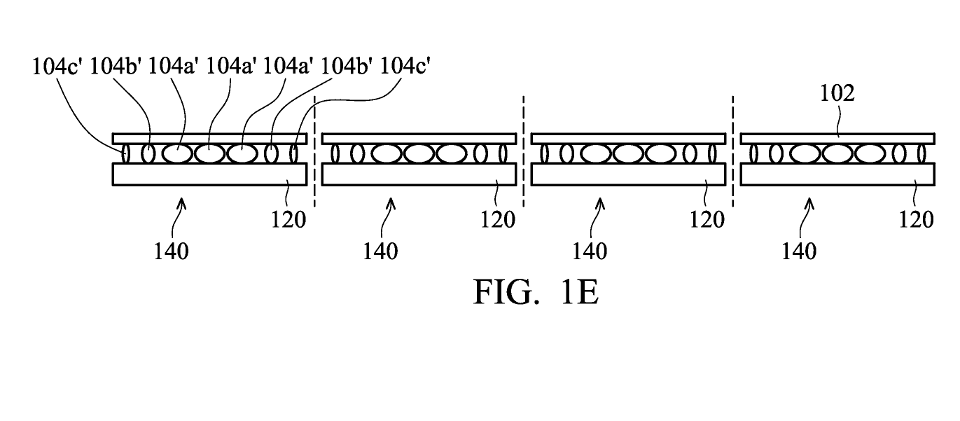

FIGS. 1A-1E are cross-sectional views of a wafer-level packaging process of a chip package according to an embodiment of the invention. As shown in FIG. 1A, a semiconductor substrate 100 is provided. The semiconductor substrate 100 has a surface 100a. The semiconductor substrate 100 is, for example, a semiconductor wafer. Therefore, the symbol 100 may represent a semiconductor wafer. The suitable semiconductor wafer may include a silicon wafer, a silicon-germanium wafer, a gallium arsenide wafer, or the like.

The semiconductor substrate 100 has chips 102. In the embodiments of the present invention, the chips 102 may include active or passive elements, or electronic components with digital or analog circuits, such as opto electronic devices, micro electro mechanical systems (MEMS), micro fluidic systems, and physical sensors for detecting the physical quantity variation of heat, light, or pressure. Particularly, a wafer scale package (WSP) process may be applied to package semiconductor chips such as image sensor devices, light-emitting diodes (LEDs), solar cells, RF circuits, accelerators, gyroscopes, micro actuators, surface acoustic wave devices, pressure sensors, ink printer heads, or power MOSFET modules. In the present embodiment, the chips 102 may be manufactured by any suitable process, such as a wafer-level CMOS process.

Since each of the chips 102 has function circuits, each of the chips 102 has a warpage according to the circuit design. For example, the warpage includes an upward warpage of the chip edge, a downward warpage of the chip edge or other irregular warpage. In general, for dispersing the stress resulted from the warpage of the chips 102, the semiconductor substrate 100 has a warpage shape corresponding to the chips 102. In some embodiments, the chips 102 of the semiconductor substrate 100 are chips with the same function or the same design. Therefore, in top view, each of the chips 102 of the semiconductor substrate 100 is a repeating unit, and the chips 102 are arranged in the semiconductor substrate 100 continuously. That is, as shown in FIG. 1A, the semiconductor substrate 100 with the chips 102 has a surface 100a with a substantial wavy shape. It should be noted that FIG. 1A only shows an embodiment of a downward warpage of the chip edge. However, persons skilled in the art may conjecture that the surface of the semiconductor substrate 100 has a wavy shape when the edges of the chips 102 warp upwardly or irregularly. Furthermore, in one embodiment, a space (not shown) is between the chips 102 to be used as a scribing line SC.

Thereafter, as shown in FIG. 1B, it shows a measurement 101 of circuit distributions on the surface 100a of each of the chips 102. In one embodiment, the measurement 101 may be performed by using a surface scattering instrument or by other measuring methods. It should be noted that the warpage shape and the warpage degree of each of the separated chips 102 formed from dicing the semiconductor substrate 100 is able to be calculated by the measurement of circuit distributions on the surface 100a of each of the chips 102.

Then, referring to FIG. 1C, according to the calculation result mentioned above, the solder balls 104 are disposed on each of the chips 102 of the semiconductor substrate 100. In one embodiment, the solder balls 104 may at least have a first size and a second size that is different from the first size. The solder balls 104 may have various sizes according to requirements. For example, the solder balls 104 may have a third size different from the first size and the second size or have more sizes. In one embodiment, the sizes of the solder balls 104a of the first size and the solder balls 104b of the second size have a positive relationship or a negative relationship to the warpage degree and the warpage direction of the chips. Alternatively, the solder balls 104 may at least have a first height and a second height that is different from the first height and other heights. For illustration purposes, the different heights are referred as different sizes in the following description. The solder balls 104 may include eutectic solder balls, lead-free solder balls or combinations thereof. For example, in some embodiments, according to the calculation results, the solder balls 104a and 104b are disposed on portions of the chips 102 with a low degree of warpage and portions of the chips 102 with a high degree of warpage, respectively, and vice versa. Therefore, there are the solder balls 104a of the first size and the solder balls 104b of the second size on each of the chips 102. In some embodiments, there are the solder balls 104c with the third size or the solder balls of other size on the chips 102. The number of the solder balls of different sizes may be varied according to the chip warpage degree or the area of the chip, and may be adjusted according to demand.

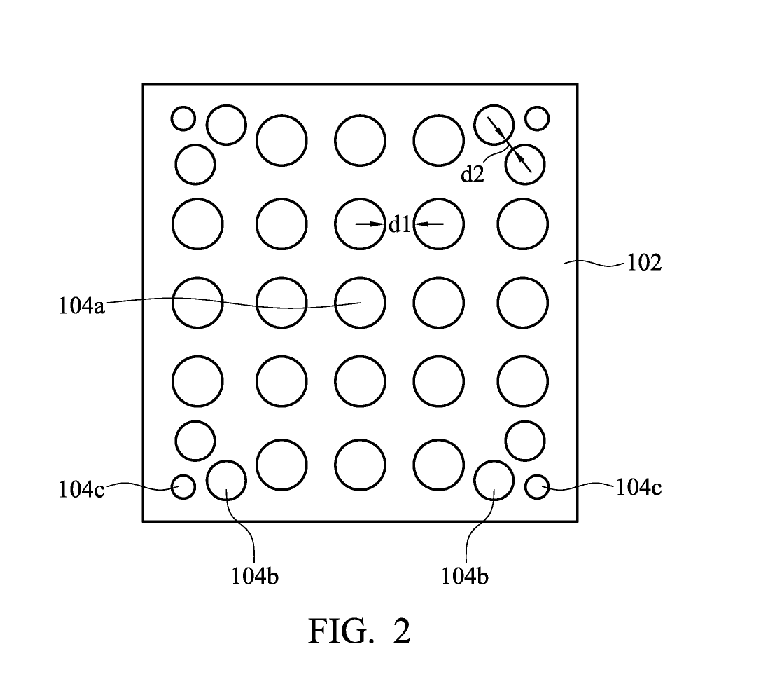

In some embodiments, the spacing d1 between the adjacent solder balls 104a of the first size is different from the spacing d2 between the adjacent solder balls 104b of the second size. For example, referring to FIG. 2, FIG. 2 is a bottom view of the chips 102 after being disposed with the solder balls 104 (as shown in FIG. 1C). As shown in FIG. 2, the spacing d1 between the adjacent solder balls 104a of the first size is different from the spacing (not shown) between the solder balls 104a and the solder balls 104b of the second size. According to the above descriptions, it is known that the spacings mentioned above are determined according to the warpage degree and the shape of the chips 102 after dicing the semiconductor substrate 100.

For example, FIG. 1C shows the embodiment in which the chip edges warp downwardly. The solder balls 104a of the first size may be disposed adjacent to the center of each of the chips 102. The solder balls 104b of the second size may be disposed adjacent to the edge of each of the chips 102. The solder balls 104c with the third size may be disposed mostly adjacent to the edge of each of the chips 102. In the present embodiment, the first size is larger than the second size, and the second size is larger than the third size.

As shown in FIG. 2, the solder balls 104b of the second size and the solder balls 104c with the third size are disposed adjacent to the corners of the chips 102. Alternatively, in other embodiments, the solder balls 104b of the second size and the solder balls 104c with the third size are arranged in one row or multiple rows concentrically surrounding the solder balls 104a (not shown) disposed adjacent to the center of each of the chips 102.

In the present embodiment, the solder balls 104a of the first size have the main functions of support and signal transmission. The solder balls 104b of the second size, the solder balls 104c with the third size and the solder balls of other sizes may also have the functions of support and electronic signal transmission. Alternatively, in other embodiments, the solder balls 104b of the second size, the solder balls 104c with the third size and the solder balls of other sizes may have the functions of support, stress compensation or heat conduction and are not connected with functional circuits of the chips 102.

Then, referring to FIG. 1D, the semiconductor substrate 100 is disposed on the packaging substrate 120 via the solder balls 104a, and the semiconductor substrate 100 and the packaging substrate 120 are diced into separated chip packages 140 along the scribing lines SC on the semiconductor substrate 100. The packaging substrate 120 is, for example, a printed circuit board, a silicon substrate with a function of electrical connection, three dimensional (3D) packaging substrate, etc. After the dicing process, the separated chips 102 may warp due to the distribution of the functional circuits of the chips 102. Therefore, the solder balls 104a, 104b and 104c may be in close contact with the packaging substrate 120.

Thereafter, referring to FIG. 1E, a reflow process is performed to the solder balls 104a, 104b and 104c, such that the solder balls 104a, 104b and 104c are deformed into solder balls 104a′, 104b′ and 104c′ by gravity, and therefore the solder balls 104a′, 104b′ and 104c′ are in close contact with the chips 102 and the packaging substrates 120. For example, since the solder balls 104a′ adjacent to the center of the chip 102 bear the main weight of the chip 102, the solder balls 104a′ are wider and shorter than the unreflowed solder balls 104a. Since the spacing between the chip 102 and the packaging substrate 120 becomes large, the solder balls 104b′ and 104c′ adjacent to the edge of the chip 102 are taller and more slender than the unreflowed solder balls 104b and 104c.

Therefore, the warpage of the chip 102 may be compensated by adjusting the size and the disposed position of the deformed solder balls 104a′, 104b′ and 104c′ and the spacing between the solder balls 104a′, 104b′ and 104c′. The solder balls 104a′, 104b′ and 104c′ may be the same height. Furthermore, the solder balls 104a′ are wider than the solder balls 104b′, and the solder balls 104b′ are wider than the solder balls 104c′. Therefore, the issue of warpage of the chip 102 may be reduced or eliminated, and the possibility of breaking the chip 102 is reduced. That is, the surface of the chip 102 is a substantially flat surface.

Therefore, the manufacturing method of the embodiment of FIGS. 1A-1E may improve the yield, and the durability and the performance of the chip packages 140 formed by the manufacturing method are significantly improved.

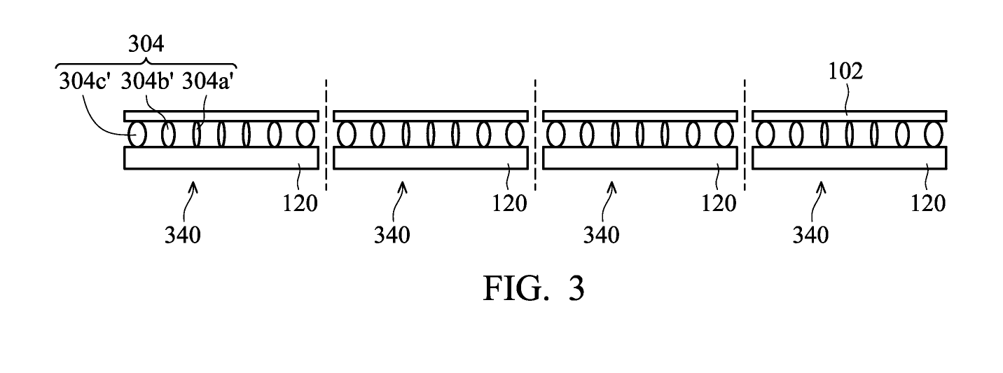

FIG. 3 shows chip packages 340 formed by the manufacturing method of the embodiment of FIGS. 1A-1E. However, the edge of the chip 102 of the chip package 340 bears the main weight of the chip. In the present embodiment and the embodiment mentioned above, same reference numbers are used to designate same or similar elements. Therefore, the materials and the manufacturing methods of the elements with the same reference numbers are provided by referring to the relative description of the embodiment of FIGS. 1A-1E.

In the present embodiment, the solder balls 304a′ of the first size may be disposed adjacent to the centers of the chips 102. The solder balls 304b′ of the second size may be disposed adjacent to the edges of the chips 102. The solder balls 304c′ with the third size may be disposed mostly adjacent to the edge of each of the chips 102. The same as the embodiment mentioned above, the solder balls 304b′ of the second size and the solder balls 304c′ with the third size may be disposed adjacent to the corners of the chips 102. Alternatively, in other embodiments, the solder balls 304b′ of the second size and the solder balls 304c′ with the third size are arranged in one row or multiple rows concentrically surrounding the solder balls 304a′ (not shown) disposed adjacent to the center of each of the chips 102. In the present embodiments, the solder balls 304a′, 304b′ and 304c′ may have the same height. The widths of the solder balls 304a′ are less than the widths of the solder balls 304b′, and the widths of the solder balls 304b′ are less than the widths of the solder balls 304c′.

Therefore, the warpage of the chip 102 may be compensated by adjusting the size and the disposed position of the deformed solder balls 304a′, 304b′ and 304c′ and the spacing between the solder balls 304a′, 304b′ and 304c′. Therefore, the issue of warpage of the chip 102 may be reduced or eliminated, and the possibility of breaking the chip 102 is reduced. That is, the surface of the chip 102 is a substantially flat surface. In the present embodiment, the solder balls 304a′ of the first size have the main functions of support and signal transmission. The solder balls 304b′ of the second size, the solder balls 304c′ with the third size and the solder balls of other sizes may also have the functions of support and electronic signal transmission. Alternatively, in other embodiments, the solder balls 304b′ of the second size, the solder balls 304c′ with the third size and the solder balls of other sizes may have the functions of support, stress compensation or heat conduction and are not connected with functional circuits of the chips 102.

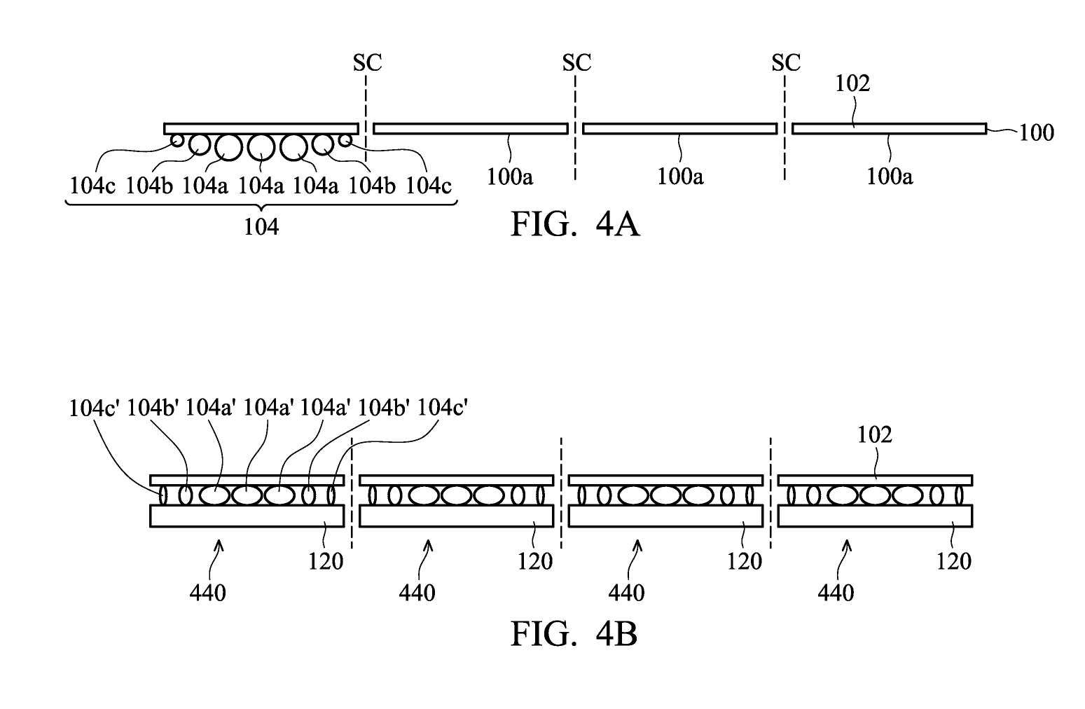

FIGS. 4A-4B are cross-sectional views of a chip-level packaging process of a chip package according to one embodiment of the invention. In the present embodiment and the embodiment mentioned above, same reference numbers are used to designate same or similar elements. Therefore, the materials and the manufacturing methods of the elements with the same reference numbers are provided by referring to the relative description of the embodiment of FIGS. 1A-1E.

As shown in FIG. 4A, the solder balls 104 are disposed on each of the separated chips 102 according to the calculation result. In one embodiment, the solder balls 104 may at least have a first size and a second size that is different from the first size. In one embodiment, the sizes of the solder balls 104a of the first size and the solder balls 104b of the second size have a positive relationship or a negative relationship to the warpage degree and the warpage direction of the chips. Alternatively, the solder balls 104 may have various sizes according to requirements. For example, the solder balls 104 may further have a third size or more sizes. For example, in some embodiments, according to the calculation results, the solder balls 104a and 104b with different sizes are disposed on portions of the chips 102 with a low degree of warpage and portions of the chips 102 with a high degree of warpage, respectively, and vice versa. Therefore, there are the solder balls 104a of the first size and the solder balls 104b of the second size on each of the chips 102. In some embodiments, there are the solder balls 104c with the third size or the solder balls of other size on the chips 102. The number of the solder balls with different sizes may be varied according to the chip warpage degree or the area of the chip, and may be adjusted according to demand.

In some embodiments, the spacing d1 between the adjacent solder balls 104a of the first size is different from the spacing d2 between the adjacent solder balls 104b of the second size. The spacings mentioned above are determined according to the warpage degree and the shape of the chips 102 after dicing the semiconductor substrate 100.

Then, referring to FIG. 4B, the separated chips 102 are bonded onto the corresponding packaging substrate 120 respectively so as to form multiple chip packages 440. Furthermore, a reflow process is performed to the solder balls 104a, 104b and 104c, such that the solder balls 104a, 104b and 104c are deformed into solder balls 104a′, 104b′ and 104c′ by gravity, and therefore the solder balls 104a′, 104b′ and 104c′ are in close contact with the chips 102 and the packaging substrates 120. For example, since the solder balls 104a′ adjacent to the center of the chip 102 bear the main weight of the chip 102, the solder balls 104a′ are wider and shorter than the unreflowed solder balls 104a. Since the spacing between the chip 102 and the packaging substrate 120 becomes large, the solder balls 104b′ and 104c′ adjacent to the edge of the chip 102 are taller and more slender than the unreflowed solder balls 104b and 104c. For example, the solder balls 104a′ are shorter than the solder balls 104b′, and the solder balls 104b′ are shorter than the solder balls 104c′. The solder balls 104a′ are wider than the solder balls 104b′, and the solder balls 104b′ are wider than the solder balls 104c′.

Therefore, the warpage of the chip 102 may be compensated by adjusting the size and the disposed position of the deformed solder balls 104a′, 104b′ and 104c′ and the spacing between the solder balls 104a′, 104b′ and 104c′. For example, the solder balls 104a′, 104b′ and 104c′ may have the same height. The solder balls 104a′ are wider than the solder balls 104b′, and the solder balls 104b′ are wider than the solder balls 104c′. Therefore, the issue of warpage of the chip 102 may be reduced or eliminated, and the possibility of breaking the chip 102 is reduced. That is, the surface of the chip 102 is a substantially flat surface. Therefore, the manufacturing method of the embodiment of FIGS. 1A-1E may improve the yield, and the durability and the performance of the chip packages 440 formed by the manufacturing method are significantly improved.

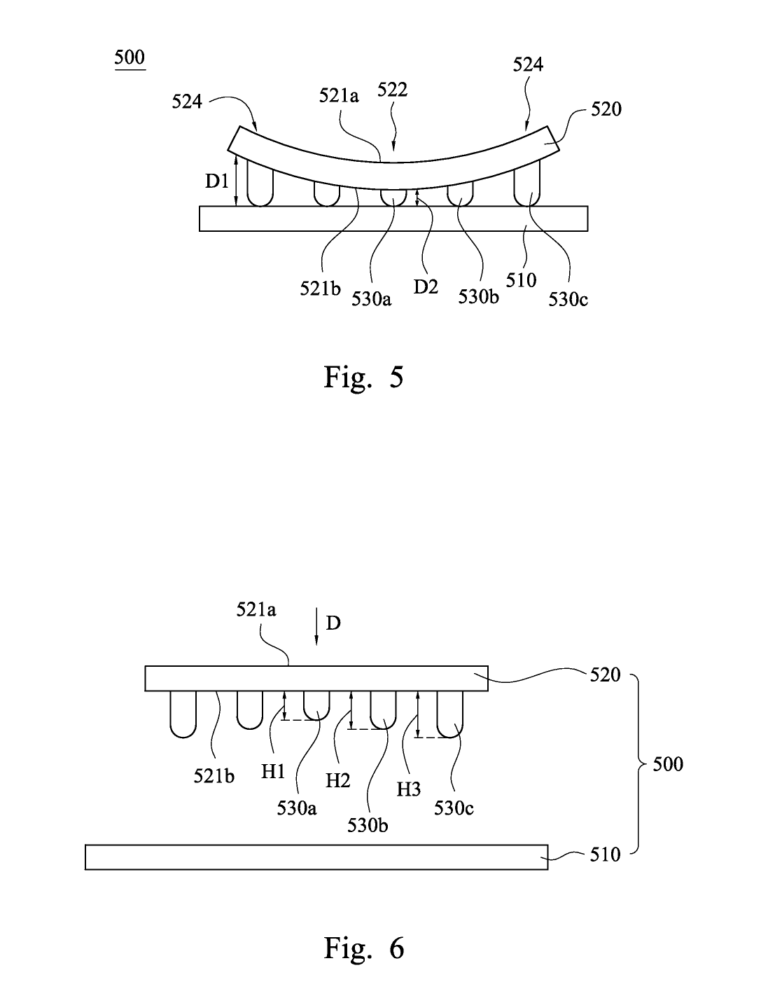

FIG. 5 is a side view of a chip package 500 according to one embodiment of the present invention. FIG. 6 is a side view of a semiconductor chip 520 shown in FIG. 5 when being mounted to a packaging substrate 510. As shown in FIG. 5 and FIG. 6, the chip package 500 includes the packaging structure 510, the semiconductor chip 520, and a plurality of conductive structures 530a, 530b, 530c. The semiconductor chip 520 has a central region 522 and an edge region 524 that surrounds the central region 522. The conductive structures 530a, 530b, 530c are between the packaging structure 510 and the semiconductor chip 520. The conductive structures 530a, 530b, 530c have different heights, and the heights of the conductive structures 530a, 530b, 530c are gradually increased from the central region 522 of the semiconductor chip 520 to the edge region 524 of the semiconductor chip 520, such that a distance D1 between the edge region 524 of the semiconductor chip 520 and the packaging structure 510 is greater than a distance D2 between the central region 522 of the semiconductor chip 520 and the packaging structure 510.

The conductive structure 530a has a height H1, the conductive structure 530b has a height H2, and the conductive structure 530c has a height H3. The height H1 is smaller than the height H2, and the height H2 is smaller than the height H3. When the semiconductor chip 520 is not mounted on the packaging structure 510 yet, the conductive structures 530a, 530b, 530c may be located on the semiconductor chip 520 or the packaging structure 510. The semiconductor chip 520 may be mounted on the packaging structure 510 in a direction D by utilizing surface-mount technology (SMT).

Since the heights H1, H2, H3 of the conductive structures 530a, 530b, 530c are gradually increased from the central region 522 of the semiconductor chip 520 to the edge region 524 of the semiconductor chip 520, the a surface 521a of the semiconductor chip 520 is a concave surface. In this embodiment, the surface 521a of the semiconductor chip 520 is a front surface of the semiconductor chip 520 (i.e., an image-sensing surface), and the surface 521a may detect light. A surface 521b of the semiconductor chip 520 is a back surface of the semiconductor chip 520, and the surface 521b may be electrically connected to the packaging structure 510 through the conductive structures 530a, 530b, 530c.

When the surface 521a of the semiconductor chip 520 is a concave surface, the surface 521a can be simulated to a retinal shape. As a result, when the surface 521a of the semiconductor chip 520 (i.e., an image-sensing surface) detects an image, light is apt to be centralized, thereby reducing the possibility of image distortion.

In this embodiment, the packaging structure 510 may be a printed circuit board. The semiconductor chip 520 may be made of a material including silicon. The semiconductor chip 520 may be an image-sensing chip, such as CMOS element, but the present invention is not limited in this regard. The conductive structures 530a, 530b, 530c may be solder balls, and the present invention is not limited to the number of the conductive structures, the shapes of the conductive structures, and the materials of the conductive structures.

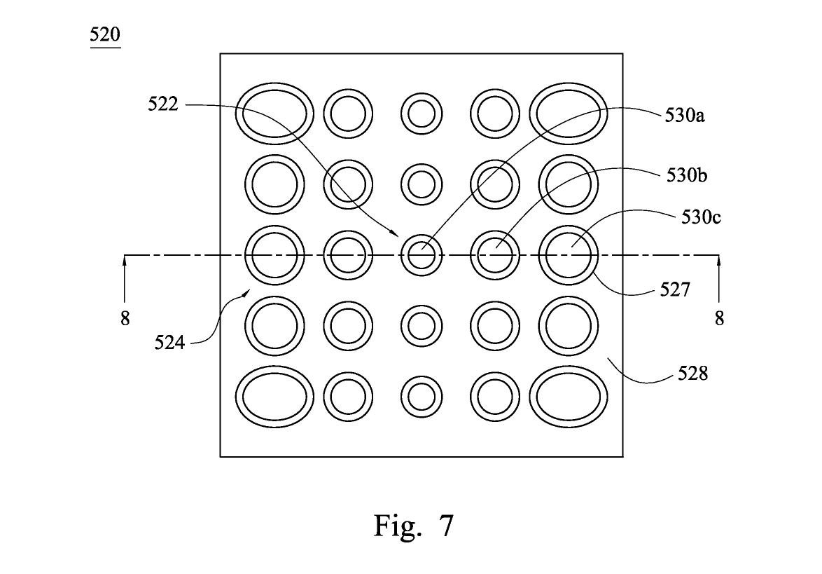

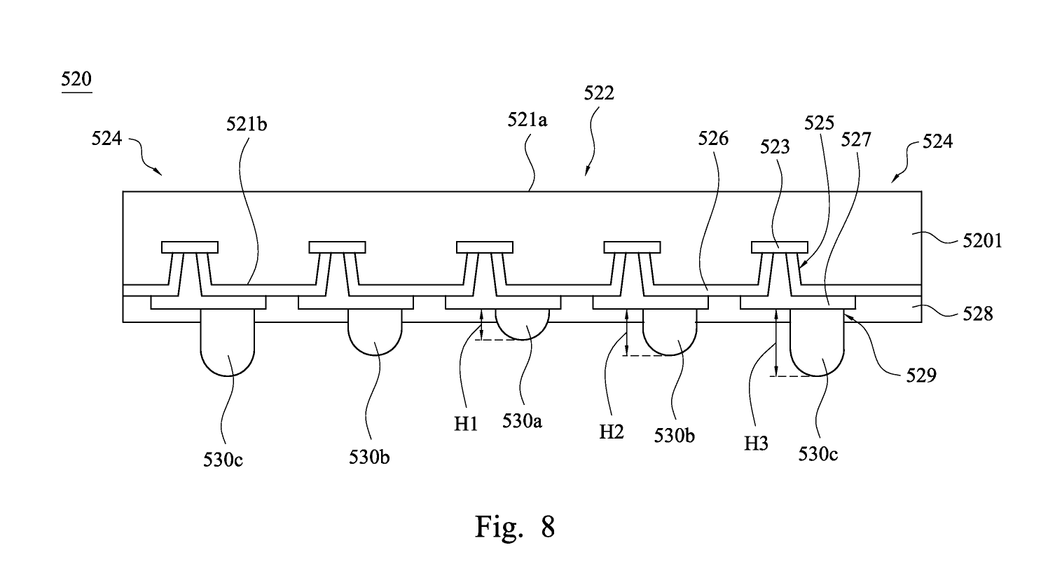

FIG. 7 is a bottom view of the semiconductor chip 520 shown in FIG. 6. FIG. 8 is a cross-sectional view of the semiconductor chip 520 taken along line 8-8 shown in FIG. 7. As shown in FIG. 7 and FIG. 8, the top view shapes of the conductive structures 530a, 530b, 530c include round, elliptical, polygonal, or a combination of shapes thereof. The semiconductor chip 520 has a semiconductor substrate 5201 (e.g., a silicon chip). The semiconductor substrate 5201 has a bonding pad 523 and a hollow region 525. The bonding pad 523 is exposed through the hollow region 525. The semiconductor chip 520 further includes an isolation layer 526. The isolation layer 526 is located on the surface 521b of the semiconductor substrate 5201 facing the packaging substrate 510 (see FIG. 1) and a surface of the semiconductor substrate 5201 surrounding the hollow region 525.

Moreover, the semiconductor chip 520 may further include a redistribution layer 527 and a protection layer 528. The redistribution layer 527 is located on the isolation layer 526 and the bonding pad 523. The protection layer 528 is located on the redistribution layer 527 and the isolation layer 526. The protection layer 528 has a plurality of openings 529 to expose the redistribution layer 527. The conductive structures 530a, 530b, 530c are located on the redistribution 527 that is in the openings 529 of the protection layer 528.

In this embodiment, the calibers of the openings 529 of the protection layer 528 are substantially the same, but the volumes of the conductive structures 530a, 530b, 530c are different. The volume of the conductive structure 530a is smaller than the volume of the conductive structure 530b, and the volume of the conductive structure 530b is smaller than the volume of the conductive structure 530c. Therefore, the height H1 of the conductive structure 530a is smaller than the height H2 of the conductive structure 530b, and the height H2 of the conductive structure 530b is smaller than the height H3 of the conductive structure 530c.

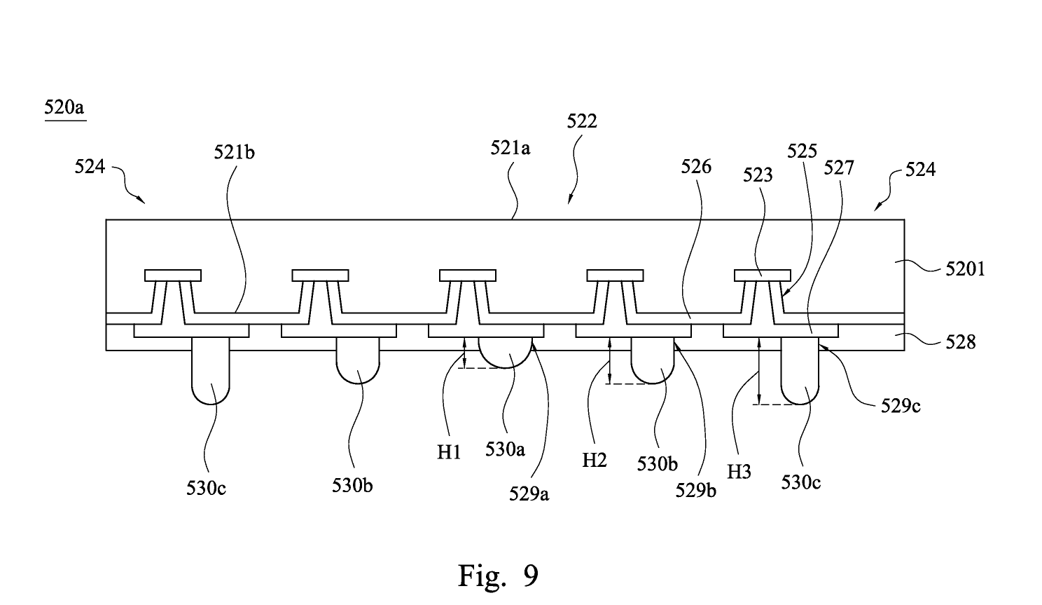

FIG. 9 is a cross-sectional view of a semiconductor chip 520a according to one embodiment of the present invention, in which the position of the cut line is the same that of FIG. 8. The semiconductor chip 520a includes the semiconductor substrate 5201, the isolation layer 526, the redistribution layer 527, and the protection layer 528. The difference between this embodiment and the embodiment shown in FIG. 8 is that the calibers of the openings 529a, 529b, 529c of the protection layer 528 of this embodiment are gradually decreased from the central region 522 of the semiconductor chip 520a to the edge region 524 of the semiconductor 520a, and the volumes of the conductive structures 530a, 530b, 530c are substantially the same.

The caliber of the opening 529a of the protection layer 528 is greater than the caliber of the opening 529b of the protection layer 528 and the caliber of the opening 529b of the protection layer 528 is greater than the caliber of the opening 529c of the protection layer 528. Therefore, the height H1 of the conductive structure 530a is smaller than the height H2 of the conductive structure 530b, and the height H2 of the conductive structure 530b is smaller than the height H3 of the conductive structure 530c.

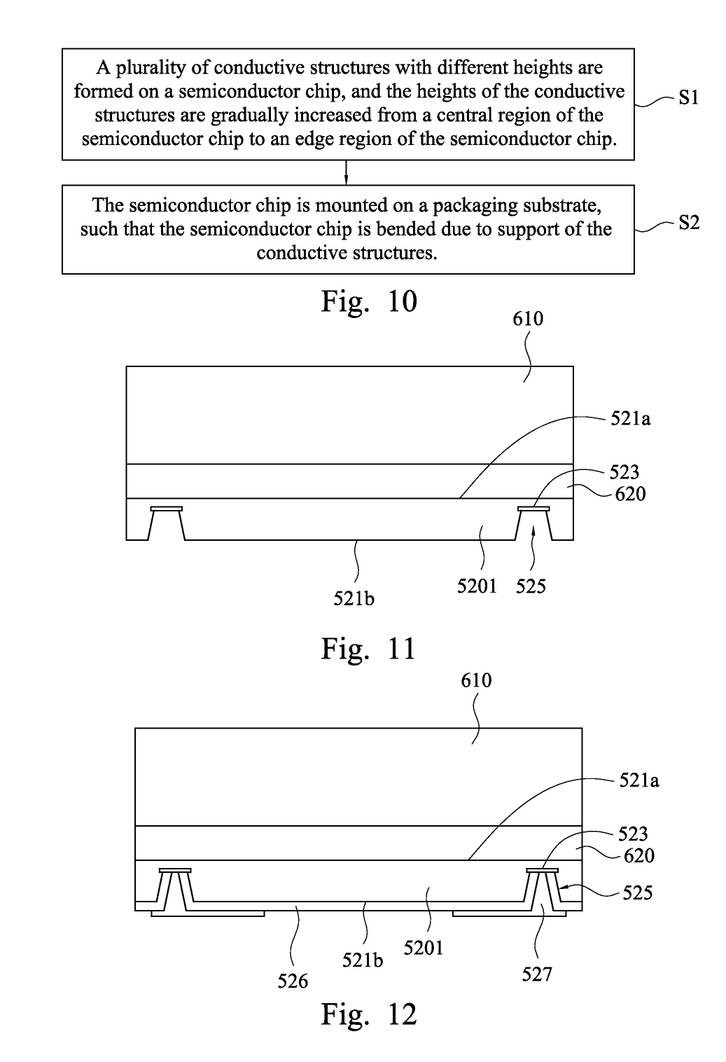

FIG. 10 is a flow chart of a method for fabricating a chip package according to one embodiment of the present invention. The method for fabricating the chip package includes the following steps. In step S1, a plurality of conductive structures with different heights are formed on a semiconductor chip, and the heights of the conductive structures are gradually increased from a central region of the semiconductor chip to an edge region of the semiconductor chip. The aforesaid conductive structures may be shown in FIG. 6. Thereafter in step S2, the semiconductor chip is mounted on a packaging substrate, such that the semiconductor chip is bended due to support of the conductive structures. The aforesaid semiconductor chip may be shown in FIG. 1.

Referring to FIG. 8, in the step for forming the conductive structures 530a, 530b, 530c with different heights on the semiconductor chip 520, a caliber of an opening of a printing nozzle may be adjusted, such that a conductive glue is printed on the semiconductor chip 520 from the opening of the printing nozzle with different calibers to form the conductive structures 530a, 530b, 530c with different heights. In this embodiment, the calibers of the openings 529 of the protection layer 528 are substantially the same, but the volumes of the conductive glue printed in the openings 529 are different, such that the conductive structures 530a, 530b, 530c with different heights can be formed after the conductive glue is solidified. In this embodiment, a ball printing process is suitable for forming the conductive structures 530a, 530b, 530c.

Referring to FIG. 9, in the step for forming the conductive structures 530a, 530b, 530c with different heights on the semiconductor chip 520a, the protection layer 528 may be formed on the redistribution layer 527 of the semiconductor chip 520a. Thereafter, the openings 529a, 529b, 529c with different calibers may be formed in the protection layer 528. The calibers of the openings 529a, 529b, 529c of the protection layer 528 are gradually decreased from the central region 522 of the semiconductor chip 520a to the edge region 524 of the semiconductor chip 520a. Afterwards, the conductive structures 530a, 530b, 530c may be placed on the redistribution layer 527 that is in the openings 529a, 529b, 529c of the protection layer 528. In this embodiment, the volumes of the conductive structures 530a, 530b, 530c are the same, but the shapes of the conductive structures 530a, 530b, 530c may be limited to the openings 529a, 529b, 529c with different calibers of the protection layer 528, thereby forming the conductive structures 530a, 530b, 530c with different heights. For example, the large opening 529a of the protection layer 528 may form the short conductive structure 530a, and the small opening 529c of the protection layer 528 may form the high conductive structure 530c. In this embodiment, a ball placement process is suitable for forming the conductive structures 530a, 530b, 530c.

It is to be noted that the connection relationship, the materials, and the fabricating method of the aforementioned elements will not be repeated. In the following description, other steps of the method for fabricating the chip package will be described.

FIG. 11 is a cross-sectional view of the hollow region 525 after being formed in the semiconductor substrate 5201 according to one embodiment of the present invention. The semiconductor substrate 5201 may be temporarily bonded on a carrier 610 by a tape 620 (e.g., a double-sided adhesive). Thereafter, the surface 521b of the semiconductor substrate 5201 may be ground to reduce the thickness of the semiconductor substrate 5201. Afterwards, the hollow region 525 may be formed in the semiconductor substrate 5201 by etching, such that the bonding pad 523 is exposed through the hollow region 525.

FIG. 12 is a cross-sectional view of the isolation layer 526 and the redistribution layer 527 after being formed on the semiconductor substrate 5201 shown in FIG. 11. After the hollow region 525 is formed, the isolation layer 526 may be formed on the surface 521b of the semiconductor substrate 5201 and a surface of the semiconductor substrate 5201 surrounding the hollow region 525. Thereafter, the redistribution layer 527 may be formed on the isolation layer 526 and in the hollow region 525, such that the redistribution layer 527 is electrically connected to the bonding pad 523.

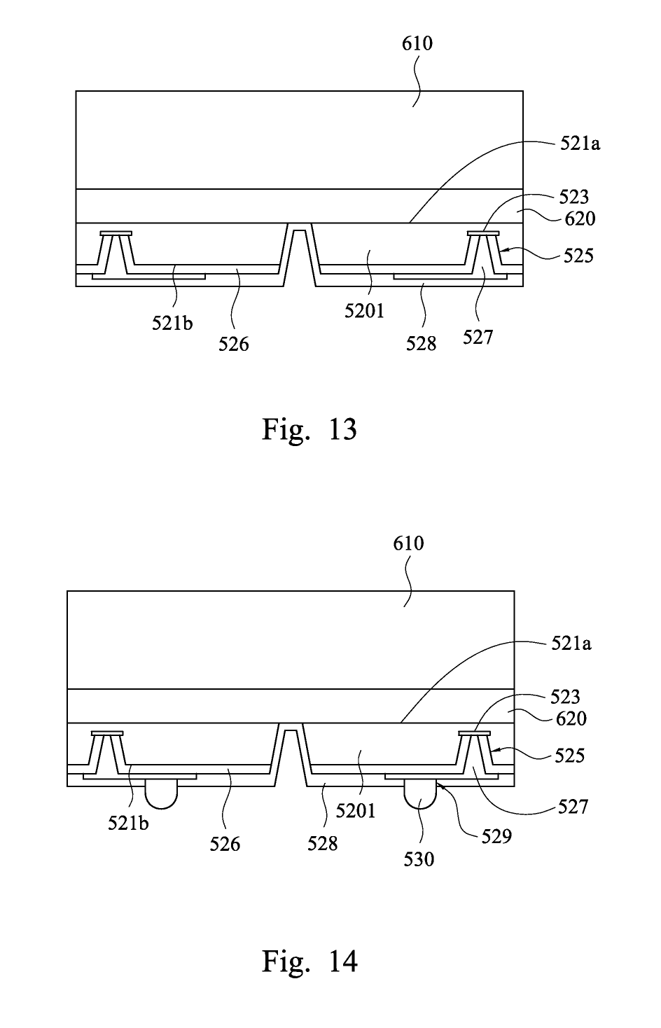

FIG. 13 is a cross-sectional view of the protection layer 528 after being formed on the isolation layer 526 and the redistribution layer 527 shown in FIG. 12. As shown in FIG. 12 and FIG. 13, after the redistribution layer 527 is formed, a notch may be formed in the semiconductor substrate 5201 by an etching process or a laser process. Thereafter, the protection layer 528 may be formed on the isolation layer 526 and the redistribution layer 527.

FIG. 14 is a cross-sectional view of a conductive structure 530 after being formed on the redistribution layer 527 shown in FIG. 13. As shown in FIG. 13 and FIG. 14, the protection layer 528 may be patterned to form the opening 529. After the opening 529 of the protection layer 528 is formed, the conductive structure 530 may be formed on the redistribution layer 527 in the opening 529. The present invention is not limited to the number of the conductive structures 530. The conductive structures 530 and the openings 529 of the protection layer 528 may be designed as the arrangement shown in FIG. 8 or FIG. 9, and will not described again.

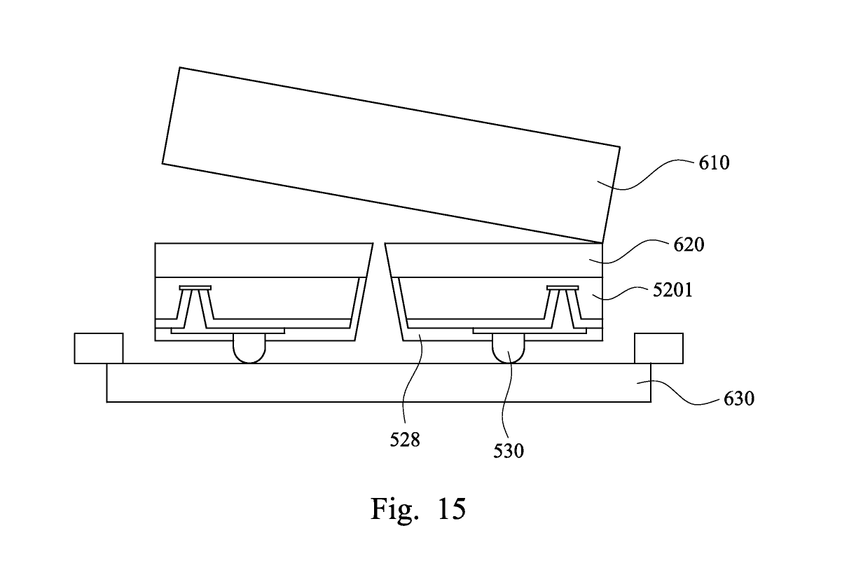

FIG. 15 is a cross-sectional view of the carrier 610 shown in FIG. 14 when being removed. As shown in FIG. 14 and FIG. 15, after the conductive structure 530 is formed, the protection layer 528 and the tape 620 above the notch shown in FIG. 14 may be pre-sawed. Afterwards, the structure after being pre-sawed may be placed on a tape 630, and the carrier 610 is separated from the tape 620.

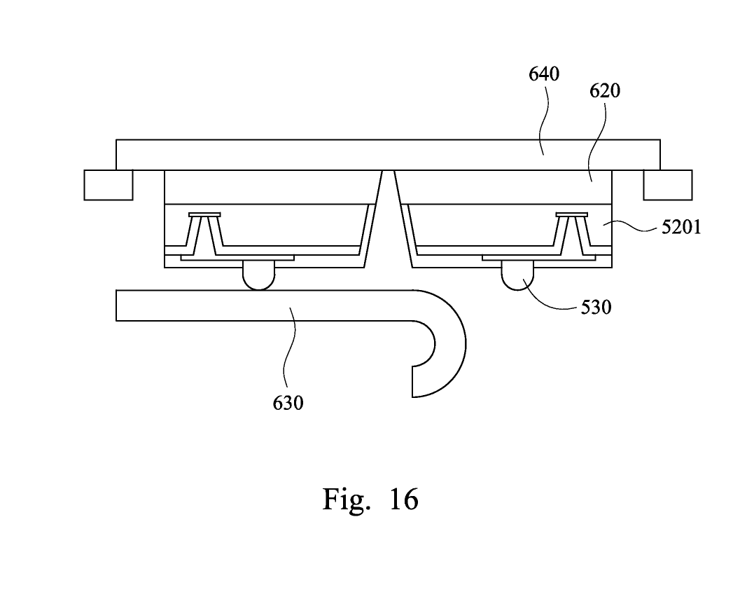

FIG. 16 is a cross-sectional view of the tape 630 shown in FIG. 15 when being removed. As shown in FIG. 14 and FIG. 15, after the carrier 610 is separated, a tape 640 may be used to adhere the tape 620 on the semiconductor substrate 5201, and thereafter the tape 630 may be removed from the conductive structure 530. In the following process, the tapes 620, 640 on the semiconductor substrate 5201 may be removed, and the semiconductor chip 520 shown in FIG. 8 or the semiconductor chip 520a shown in FIG. 9 can be obtained.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A chip package, comprising:
a packaging substrate;
a semiconductor chip having a central region and an edge region that surrounds the central region; and
a plurality of conductive structures between the packaging substrate and the semiconductor chip, wherein the conductive structures have different heights, and the heights of the conductive structures are gradually increased from the central region of the semiconductor chip to the edge region of the semiconductor chip, such that a distance between the edge region of the semiconductor chip and the packaging substrate is greater than a distance between the central region of the semiconductor chip and the packaging substrate.

2. The chip package of claim 1, wherein top view shapes of the conductive structures comprise round, elliptical, polygonal, or a combination of shapes thereof.

3. The chip package of claim 1, wherein the semiconductor chip has a semiconductor substrate, the semiconductor substrate has a bonding pad and a hollow region, the bonding pad is exposed through the hollow region, and the semiconductor chip further comprises:
an isolation layer located on a surface of the semiconductor substrate facing the packaging substrate and a surface of the semiconductor substrate surrounding the hollow region.

4. The chip package of claim 3, wherein the semiconductor chip further comprises:
a redistribution layer located on the isolation layer and the bonding pad.

5. The chip package of claim 4, wherein the semiconductor chip further comprises:
a protection layer located on the redistribution layer and the isolation layer, wherein the protection layer has a plurality of openings to expose the redistribution layer.

6. The chip package of claim 5, wherein the conductive structures are located on the redistribution layer in the openings of the protection layer.

7. The chip package of claim 5, wherein calibers of the openings of the protection layer are gradually decreased from the central region of the semiconductor chip to the edge region of the semiconductor chip.

8. A method for fabricating a chip package, comprising:
(a) forming a plurality of conductive structures with different heights on a semiconductor chip, wherein the heights of the conductive structures are gradually increased from a central region of the semiconductor chip to an edge region of the semiconductor chip; and
(b) mounting the semiconductor chip on a packaging substrate, such that the semiconductor chip is bended due to support of the conductive structures.

9. The method for fabricating the chip package of claim 8, wherein step (a) comprises:
adjusting a caliber of an opening of a printing nozzle, such that a conductive glue is printed on the semiconductor chip from the opening of the printing nozzle with different calibers to form the conductive structures with different heights.

10. The method for fabricating the chip package of claim 8, further comprising:
forming a protection layer on a redistribution layer of the semiconductor chip; and
forming a plurality of openings with different calibers in the protection layer, wherein the calibers of the openings of the protection layer are gradually decreased from the central region of the semiconductor chip to the edge region of the semiconductor chip.

11. The method for fabricating the chip package of claim 10, wherein step (a) comprises:
placing the conductive structures on the redistribution layer in the openings of the protection layer.
